(19) United States
(12) Patent Application Publication
(10) Pub. No.: US 2002/0175372 A1
(43) Pub. Date: Nov. 28, 2002

(54) Semiconductor device and method for manufacturing semiconductor device

(76) Inventor: Teruo Takizawa, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 10/076,055

(22) Filed: Feb. 14, 2002

(30) Foreign Application Priority Data
Feb. 16, 2001 (JP) 2001-39611

(51) Int. Cl. H01L 27/01; H01L 27/12; H01L 31/0392

(52) U.S. Cl. 257/347

(57) ABSTRACT

A field effect transistor formed on a SOI substrate is equipped with a gate (102) formed on a substrate, a source (103) and a drain (104) each spaced a specified distance from a crystal region below the gate, a first extension region (110) that extends in a channel formed between the source and an area below the gate, and a second extension region (111) that extends in a channel formed between the drain and an area below the gate, wherein junction depths (Xs, Xd) of the first and second extension regions is formed shallower than junction depths (Xt) of the source region (103) and the drain region (104).

### TECHNICAL FIELD OF THE INVENTION

The present invention relates to a semiconductor device and a method for manufacturing the same, and more particularly to a semiconductor device including a insulated gate field effect transistor and a method for manufacturing the same.

### BACKGROUND OF THE INVENTION

A insulated gate field effect transistor having a conventional single drain structure has a structure shown in FIG. 5, in which a gate 101, a source 103 and a drain 104 are formed in a semiconductor crystal, and transfer of carriers (current) is controlled by exerting a bias applied to the gate to the semiconductor crystal immediately below the gate through a gate oxide film.

In recent years in particular, demands on even higher IC integration have led to requirements in further miniaturization of the device size, such that a shorter gate length L is necessarily designed. Currently, the channel length has become sub-micron. When the channel length becomes such a short length, a technical problem, i.e., a so-called “short channel effect” occurs.

The short-channel effect is generally classified in two problems. For one, this leads to a reduction in the carrier mobility caused by an increase in the electric field strength, saturation of the drift speed, and an increase in the kinetic energy of carriers (hot carrier effect). For the other, the gradual approximation cannot be established because changes in the electric field in the channel in a transverse direction thereof are not negligible compared to changes in the electric field in a lateral direction thereof. As a result, the potential distribution, current distribution and carrier distribution in the channel, in particular, adjacent to the drain region become two-dimensional and even three-dimensional, which results in occurrences of deterioration of the sub-threshold characteristic, non-saturation phenomenon of the drain current due to punch-through, and channel length dependency of the threshold voltage (Vth). However, there are strong demands on realizing semiconductor devices that can control such a short-channel effect even in a region where the gate length becomes sub-micron or even in a region where the gate length becomes sub 0.1 micron.

In the mean time, a technology to fabricate a semiconductor device on a semiconductor-on-insulator (SOI) substrate in which an embedded oxide film layer is formed in a silicon wafer, for the purpose of attaining higher speed and lower power consumption in semiconductor devices, is attracting attention. A field effect transistor fabricated on a SOI substrate can reduce the junction capacitance immediately below the source and drain by about 30-40% compared to that formed on an ordinary bulk wafer, and therefore substantially improve the gate delay time and the power consumption. Accordingly, higher speed and lower power consumption of semiconductor devices can be expected.

However, it is still difficult to control the short-channel effect described above even in a field effect transistors fabricated on a SOI substrate. In particular, in a field effect transistor in a fully depleted operation mode, the entire semiconductor film layer is fully depleted, and therefore a punch-through phenomenon is apt to occur in a region adjacent to the embedded oxide film. This is a remarkable example of the short-channel effect. In the conventional technology, it is believed to be a single solution to make the semiconductor film thinner to suppress the punch-through phenomenon that may occur adjacent to the embedded oxide film.

In a conventional semiconductor device including a insulated gate field effect transistor fabricated on a SOI substrate, the short-channel effect is controlled by thinning the semiconductor film. However, thinning of the semiconductor film at a region where the gate length becomes sub-micron or sub 0.1 micron is difficult to attain a sufficient uniformity in view of the current SOI wafer fabrication technique. Furthermore, even if a semiconductor thin film were obtained across the entire wafer, field effect transistors formed on such a semiconductor thin film may have deviations in their threshold voltages and problems of parasitic resistance at sources and drains.

### SUMMARY OF THE INVENTION

The present invention is made in view of the problems discussed above, and its object is to reduce deviations in the threshold voltage and lower the parasitic resistance at source and drain and also to suppress the short-channel effect by additionally forming an extension region that extends between each of the source and drain regions and a channel region formed on a SOI substrate. This provides a high-speed, low power consumption and highly-integrated semiconductor device.

To achieve the object described above, a semiconductor device in accordance with the present invention pertains to a field effect transistor formed on a SOI substrate, the semiconductor device characterized in comprising: a gate region formed on a semiconductor film of the SOI substrate; source and drain regions each formed spaced a specified distance from a channel region formed in the semiconductor film below the gate region; a first extension region that extends from the source region to the channel region; and a second extension region that extends from the drain region to the channel region, wherein junction depths of the first and second extension regions are formed to be shallower than junction depths of the source region and the drain region.

By the structure described above, a leak current between the source and the drain caused by the short-channel effect can be reduced.

Preferably, the junction depth of each of the first and second extension regions is 50% or less of the junction depth of each of the source region and the drain region.

Also, preferably, the impurity at the first and second extension regions is activated by a laser annealing method.

Also, preferably, the semiconductor device described above is a semiconductor device that operates in a fully depleted operation mode.

Furthermore, preferably, the SOI substrate is a substrate composed of a glass substrate, a quartz substrate or another insulation substrate and a semiconductor film formed thereon.

Also, a method for manufacturing a semiconductor device in accordance with the present invention pertains to a method for manufacturing a field effect transistor to be formed on a SOI substrate, the method characterized in comprising: a first step of forming a gate electrode on a semiconductor layer of the SOI substrate; a second step of implanting an impurity with a high concentration in regions spaced specified distances from the gate electrode to form source and drain regions; a third step of introducing an impurity in regions between a channel region formed under the gate electrode and the source and drain regions to a depth shallower than the source and drain to form extension regions of the source and drain regions; and a fourth step of electrically activating the extension regions by a laser anneal method.

By the composition described above, a semiconductor device in which a leak current between the source and the drain that may be caused by the short-channel effect can be manufactured.

Preferably, the third step is characterized in extremely shallowly implanting an impurity by a plasma doping method.

Preferably, the junction depth of the extension regions is formed to be 50% or less of the junction depth of each of the source region and the drain region.

### BRIEF DESCRIPTION OF THE DRAWINGS

FIG. 1 is a cross-sectional view of an nMOSFET having an extension region in accordance with the present invention.

FIG. 2 is an illustration for describing a process for manufacturing an nMOSFET having an extension region in accordance with the present invention.

FIG. 3(a) is a graph for describing a result of measurement of the transfer characteristic of nMOSFETs having an extension region in accordance with the present invention.

FIG. 4 is a graph for describing the effect of junction depths of extension regions exerted on leak currents.

FIG. 5 is a cross-sectional view of an nMOSFET with a single drain structure.

FIG. 6 is a cross-sectional view of an nMOSFET with an LDD structure.

### DETAILED DESCRIPTION OF THE PREFERRED EMBODIMENTS OF THE INVENTION

Embodiments of the present invention will be described below with reference to the accompanying drawings.

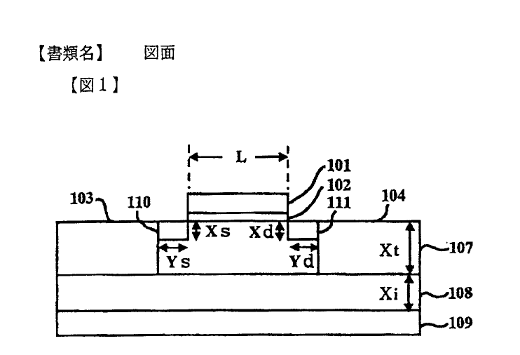

FIG. 1 shows a cross-sectional view for describing a structure of a semiconductor device in accordance with an embodiment of the present invention.

In this embodiment, an nMOSFET is formed using a semiconductor (silicon: Si) formed on a dielectric substrate as a SOI substrate. Also, a semiconductor layer 107 is formed with a film thickness Xt on a substrate 109 through a dielectric layer 108 with a film thickness Xi.

A gate 101 is formed on a gate oxide film 102 that is formed by thermally oxidizing a surface of the semiconductor layer 107 and has a gate length L. An n-type source region 103 or a drain region 104, which is separated a distance Ys or Yd from a gate forming region, is formed in the semiconductor layer 107.

In regions of the separation distances Ys and Yd between each of the source region 103 and the drain region 104 and the gate forming region, extension regions (110 and 111) are formed by doping an impurity such that the extension regions become an n-type conductivity type that is the same conductivity type of the source region or the drain region, and respectively have junction depths Xs and Xd independently of the source region 103 and the drain region 104.

Values of the above-described Xs, Xd, Ys and Yd can be freely designed according to desired device characteristics. Further, the Xs and Xd or the Ys and Yd may be designed to have the same values or different values.

It is noted that the substrate described above is not limited to a SOI substrate that is fabricated by a lamination method or a SIMOX method, but may be a substrate in which a semiconductor film is formed on a glass substrate, a quartz substrate or any another insulation substrate.

Also, the semiconductor film in which elements are formed is not limited to single crystal, but may be a film of polycrystal or amorphous crystal.

Furthermore, the crystal of the semiconductor film is not limited to a single element crystal such as silicon (Si), but may be a III-V compound semiconductor such as GaAs, a II-VI compound semiconductor such as ZnSe, or a IV-IV compound semiconductor such as semiconductor integrated circuit.

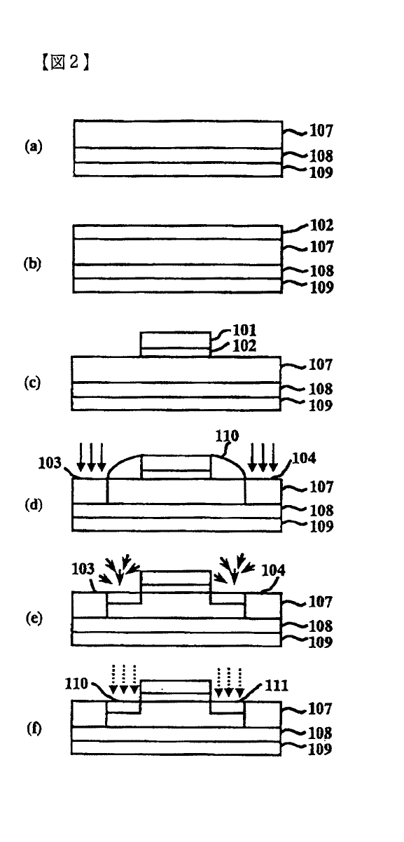

FIG. 2 illustrates a process for manufacturing a semiconductor device having the structure described above.

FIG. 2(a) shows a SOI substrate that is fabricated by, for example, a lamination method or a SIMOX method, and includes a silicon film 107 having a thickness Xt that is a portion of the semiconductor crystal in which a device structure is formed. Also, the semiconductor film is formed on a dielectric film (SiO₂) 108 having a thickness Xi.

First, the substrate is subject to a 95% wet thermal oxidation at 750-800° C. to form an oxide film 102 having a thickness of 3 nm (FIG. 2(b)).

It is noted that the oxide film 102 needs not to b an oxide of the substrate (silicon in the present embodiment) 107, but a high dielectric constant material such as tantalum oxide can be used as the oxide film (dielectric film).

For example, polysilicon is grown to a thickness of about 100 nm on the oxide film 102. Photoresist is coated on this film, and a gate electrode (gate wiring) 101 and the oxide film (gate dielectric film) 102 are patterned (FIG. 2(c)) by exposure, development and etching of a gate pattern using an excimer exposure technique or a EB exposure technique.

Further, a sidewall 110 of a nitride film with a thickness of about 0.2 μm is formed on a sidewall of the gate electrode, and then an impurity is injected in source and drain regions 103 and 104 by an ion implantation method (FIG. 2(d)).

The sidewall of a nitride film is removed by heated phosphoric acid, and the impurity is activated by a thermal anneal treatment for about 10 seconds at 1000° C.

Then, an impurity is very shallowly injected by a plasma doping method in the silicon film 107 between the gate region and the source region and between the gate region and the drain region (FIG. 2(e)). Furthermore, in order to activate the impurity while keeping its very shallow and highly concentrated profile, a laser anneal is conducted with an energy density of about 0.1-1 J/cm², using, for example, YAG laser or XeCl laser (FIG. 2(f)).

By the process described above, the MOS transistor shown in FIG. 1 is obtained.

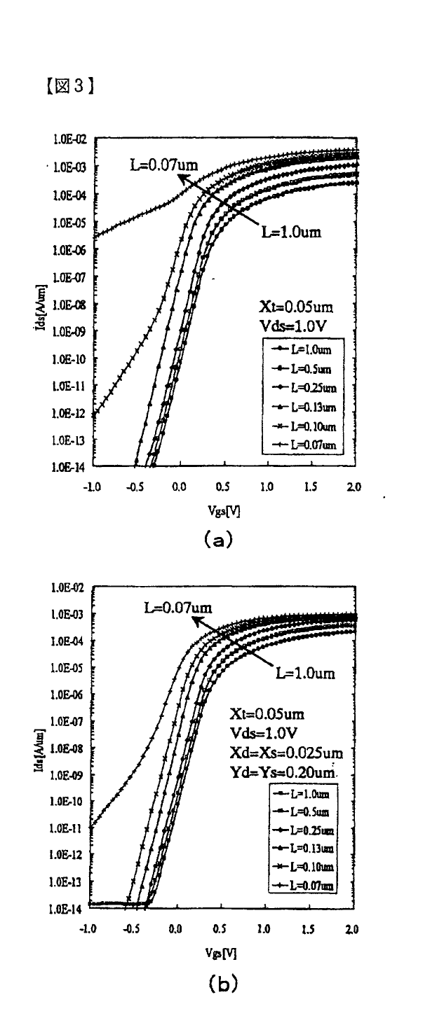

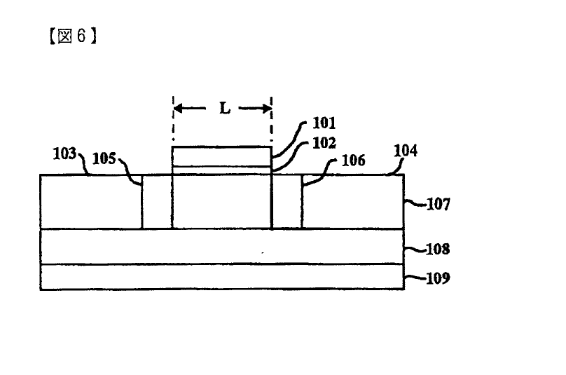

FIG. 3 compares transfer characteristics of the nMOSFETs thus manufactured, and transfer characteristics of the nMOSFETs having the conventional single drain structure shown in FIG. 5.

It is noted that, in the FETs with either of the structures, the silicon film thickness of the SOI is 50 nm and the voltage (Vds) between the source and the drain is 1.0V, and elements are formed with their gate length (L) being changed from 1.0 μm to 0.07 μm.

Also, the nMOSFETs of the present invention are formed under conditions in which Xs=Xd=0.025 μm, Yx=Yd=0.20 μm, and the impurity concentration of both of the first and second extension regions is Nex=1×10¹⁹ cm⁻².

According to the transfer characteristics of the nMOSFETs with a single drain structure, as shown in FIG. 3(a), a leak current in OFF state, in other words, a punch-through current that is caused by the short-channel effect increases as the gate length becomes shorter. When Vgs=−0.5 V, a leak current of about 1.0×10⁻⁹ A/μm for the gate length L=0.10 μm, and a leak current of about 1.0×10⁻⁵ A/μm for the gate length L=0.07 μm occur.

On the other hand, according to the transfer characteristics of the nMOSFETs in accordance with the present invention, as shown in FIG. 3(b), although there is a tendency that the leak current increases with shortening of the gate length, a leak currents are suppressed to about 1.0×10⁻¹⁴ A/μm for the gate length L=0.10 μm, and about 1.0×10⁻⁹ A/μm for the gate length L=0.07 μm, such that the leak current is reduced by 4-5 digits compared to the nMOSFETs with a conventional single drain structure.

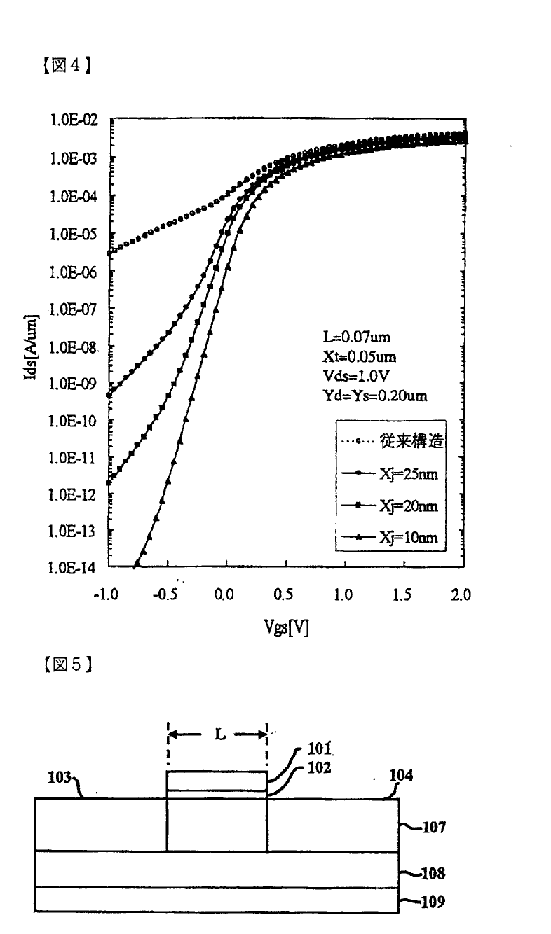

FIG. 4 shows Xs and Xd dependency of leak currents (Ids) of the nMOSFETs of the present invention.

In the present embodiment, leak currents are measured when Xs=Xd=Xj. Also, the Si film is formed with Xt=50 nm, the gate length being L=0.07 μm, and the drain voltage being Vd=1.0V, and the junction depth Xj of the first and second extension regions is changed from 25 nm to 10 nm.

The nMOSFET with a structure of Xj=25 nm has a leak current of about 1.0×10⁻⁹ A/μm at Vgs=−0.5 V. The leak current is reduced to about 1.0×10⁻¹¹ A/μm in the nMOSFET with a structure of Xj=20 nm, and further reduced to about 1.0×10⁻¹³ A/μm in the nMOSFET with a structure of Xj=10 nm.

The leak current of the nMOSFET with the structure of Xj=10 nm is reduced, in effect, by about four digits compared to the leak current of the nMOSFET with Xj=25 nm, and by about two digits compared to the leak current of the nMOSFET with Xj=20 nm, which are nMOSFETs with the conventional single drain structure.

In other words, it can be argued, with respect to the Xj dependency of the leak current while device parameters other than the junction depth Xj of the extension regions are fixed, that the leak current is reduced as the junction depth Xj becomes shallower.

The reduction of leak currents in the OFF state improves at the same time the sub-threshold characteristic and the channel length dependency of the threshold voltage. In other words, this indicates that the short-channel effect is suppressed.

In this manner, it is understood that, by providing the nMOSFET structure of the present invention, leak currents can be substantially reduced compared to nMOSFETs with the conventional single drain structure; and forming the junction depth (Xs and Xd) of the extension regions shallow compared to the junction depth of the source and drain regions is effective in further reducing leak currents.

In particular, it is understood that setting the junction depth of the first and second extension regions at 50% or less of the junction depth of each of the source and the drain is particularly effective.

As described above, in accordance with the present invention, the junction depth of extension regions in a semiconductor device is made shallow to suppress the short-channel effect. By this, a semiconductor layer on an embedded dielectric layer does not need to be thinned more than necessary. Therefore, this can provide a highly-integrated, high-speed and low power consumption semiconductor device without having problems of deviations in the threshold voltage or source and drain parasitic resistance.

It is noted that the semiconductor device of the embodiment described above is an NMOSFET that operates in a fully depleted operation mode. However, the present invention is not limited to this embodiment, and may be other semiconductor devices such as a field effect transistor that operates in a partially depleted operation mode.

Differences between the structure of the present invention and the LDD structure shown in FIG. 6 will be described below.

An electric field strength E is defined as a negative inclination of a potential as follows:

E=−dΦ/dx

As a consequence, the electric field strength adjacent to the drain becomes extremely high as the MOSFET is miniaturized.

When an area adjacent to the drain has a high electric field, hot carriers are generated, and therefore the reliability of the device is substantially reduced.

More concretely, the following phenomenon occurs. Hot carriers are injected in the gate oxide film and remain in the oxide film as a fixed charge. As the device is operated for a long time, hot carriers that are injected in the oxide film further increase, and the threshold voltage Vth gradually changes.

One of the structures that have been devised to solve the problem described above is an LDD structure (FIG. 6). An “LDD structure” stands for a “Lightly Doped Drain structure”, which is formed in a semiconductor crystal from a gate 101, a source 103, a drain 104 and LDD regions (105 and 106) formed between the gate and the source and between the gate and drain.

Transfer of carriers (current) from the source to the drain is controlled by exerting a bias applied to the gate to portion of the semiconductor crystal immediately below the gate through a gate oxide film 102. Here, the LDD region is intentionally doped with an impurity at a low concentration compared to the impurity concentration of the drain region, which is a structure that is devised to cope with hot carriers that are generated in association with miniaturization of ICs.

More specifically, let us consider an nMOS on a P-type substrate. First, regions adjacent to a source and a drain are changed to n⁻ regions with phosphorous (P) of a low concentration, and then the source and drain are formed to be in n⁺ with arsenic (As) of a high concentration. By this, the boundary between the impurity diffusion region and the p-type substrate has a gentle impurity concentration distribution, and the electric field, and the electric field adjacent to the drain in particular, is alleviated such that generation of hot carriers is suppressed.

In other words, while the separation between the source and the drain and the channel length are maintained constant, an impurity diffusion region of a low concentration is formed adjacent to the gate as part of the source or the drain to thereby lower the electric field strength adjacent to the drain.

In contrast, in the MOSFET structure of the present invention, while the gate length (in other words, the channel length) is kept constant, an extension region that extends between the source region or the drain region and the channel region is formed independently of the source region or the drain region.

Moreover, the width (Ys and Yd) of the extension region may be changed according to requirements in the device design to thereby change the source-drain separation (=L+Ys+Yd), such that the electric field distribution between the source and the drain can be freely determined. As a result, the generation of leak current due to punch-through that results from the short-channel effect can be suppressed without harming high-speed operation of a semiconductor device.

### EFFECTS OF THE INVENTION

As described above, in a semiconductor device in accordance with the present invention, since an extension region is formed between a channel and each of a source and a drain formed on a SOI substrate, leak current resulting from punch-through that is caused by the short-channel effect can be suppressed. This eliminates the necessity of thinning semiconductor thin films more than necessary, and can provide a highly-integrated, high-speed and low power consumption semiconductor device without having problems of deviations in the threshold voltage or source and drain parasitic resistance.

What is claimed is:

1. A semiconductor device comprising a field effect transistor formed on a SOI substrate, the semiconductor device characterized in comprising:
a gate region formed on a semiconductor film of the SOI substrate;
source and drain regions each spaced a specified distance from a channel region formed in the semiconductor film below the gate region;
a first extension region that extends from the source region to the channel region; and
a second extension region that extends from the drain region to the channel region,
wherein junction depths of the first and second extension regions are formed to be shallower than junction depths of the source region and the drain region.

2. A semiconductor device according to claim 1, wherein the junction depth of each of the first and second extension regions is 50% or less of the junction depth of each of the source region and the drain region.

3. A semiconductor device according to claim 1 or claim 2 characterized in operating in a fully depleted operation mode.

4. A semiconductor device according to any one of claim 1 through claim 3, wherein the SOI substrate is a substrate composed of a glass substrate, a quartz substrate or another insulation substrate and a semiconductor film formed thereon.

5. A method for manufacturing a semiconductor device, comprising a method for manufacturing a field effect transistor to be formed on a SOI substrate, the method characterized in comprising:
a first step of forming a gate electrode on a semiconductor layer of the SOI substrate;
a second step of implanting an impurity with a high concentration in regions spaced specified distances from the gate electrode to form source and drain regions;
a third step of introducing an impurity in regions between a channel region formed under the gate electrode and the source and drain regions to a depth shallower than the source and drain to form extension regions of the source and drain regions; and
a fourth step of electrically activating the extension regions by a laser anneal method.

6. A method for manufacturing a semiconductor device according to claim 5, wherein the third step includes extremely shallowly implanting an impurity by a plasma doping method.

7. A method for manufacturing a semiconductor device according to claim 6, wherein the third step includes activating the impurity by a laser anneal method.

8. A method for manufacturing a semiconductor device according any one of claim 5 through claim 7, wherein the junction depth of the extension regions is formed to be 50% or less of the junction depth of each of the source region and the drain region.
